(19) United States
(12) Patent Application Publication
(10) Pub. No.: US 2018/0128999 A1
(43) Pub. Date: May 10, 2018

(54) PHOTOELECTRIC CONVERSION ELEMENT AND OPTICAL MODULE

(71) Applicant: Murata Manufacturing Co., Ltd., Nagaokakyo-shi (JP)

(72) Inventors: Takatoshi Kato, Nagaokakyo-shi (JP); Keiji Iwata, Nagaokakyo-shi (JP)

(21) Appl. No.: 15/867,851

(22) Filed: Jan. 11, 2018

Related U.S. Application Data
(63) Continuation of application No. PCT/JP2016/072892, filed on Aug. 4, 2016.

(30) Foreign Application Priority Data
Aug. 12, 2015 (JP) 2015-159293

(51) Int. Cl. G02B 6/42; H01L 31/0203; H01L 31/02; H01L 31/0232

(52) U.S. Cl. CPC G02B 6/4206; H01L 31/0203; H01S 5/042; H01L 31/02325; G02B 6/4219; H01L 31/02005

(57) ABSTRACT

A surface emitting element that is a photoelectric conversion element and includes a substrate, first and second electrode patterns, and first and second electrode structures. The substrate has a first surface and a second surface facing each other. The substrate emits light from the first surface. The first and second electrode patterns are formed on the substrate and used for photoelectric conversion. The first electrode structure is connected to the first electrode pattern, and the second electrode structure is connected to the second electrode pattern. The first and second electrode structures are formed on a first side surface that is orthogonal to the first and second surfaces of the substrate in shapes protruding from the first side surface.

### CROSS REFERENCE TO RELATED APPLICATIONS

The present application is a continuation of PCT/JP2016/072892 filed Aug. 4, 2016, which claims priority to Japanese Patent Application No. 2015-159293, filed Aug. 12, 2015, the entire contents of each of which are incorporated herein by reference.

### TECHNICAL FIELD

The present disclosure relates to a photoelectric conversion element such as a surface emitting element or a light-receiving element having a light-receiving surface, and an optical module including the photoelectric conversion element.

### BACKGROUND

A large number of surface emitting elements such as VCSEL (Vertical Cavity Surface Emitting Laser) have currently been put to practical use. A surface emitting element is used, for example, in an optical transmission module as disclosed in Patent Document 1 (identified below).

The optical transmission module described in Patent Document 1 includes a surface emitting element, an optical fiber, and a support substrate. The surface emitting element and the optical fiber are mounted on the support substrate. The light-emitting surface of the surface emitting element is orthogonal to the surface of the support substrate. The optical fiber is disposed close to the light-emitting surface of the surface emitting element.

In the configuration described in Patent Document 1, a body of the surface emitting element is provided with irregularities in order to position the surface emitting element on the support substrate. The support substrate is provided with a groove into which the shape of the irregularities is fitted.

Patent Document 1: Japanese Patent Application Laid-Open No. 2010-78806.

However, in the configuration described in Patent Document 1, in order to improve the positioning accuracy, it is necessary to form complicated irregularities on a body of the surface emitting element and the support substrate. For this reason, the construction method becomes complicated and the number of steps increases. Further, due to complication of such a construction method and an increase in the number of steps, there is a possibility that the dimensional accuracy deteriorates due to accumulation of manufacturing errors in each step and the construction method.

### SUMMARY OF THE INVENTION

Accordingly, an object of the present disclosure is to provide a photoelectric conversion element capable of obtaining high placement accuracy with a simple structure and a simple step.

Thus, a photoelectric conversion element is disclosed that includes a substrate, first and second electrode patterns, and first and second electrode structures. The substrate has an optical element that emits light or receives light from a main surface. The first electrode pattern and the second electrode pattern are formed on the substrate and connected to the optical element. The first electrode structure is connected to the first electrode pattern, and the second electrode structure is connected to the second electrode pattern. The first and second electrode structures are formed on a first side surface that is orthogonal to a first surface and a second surface of the substrate in shapes protruding from the first side surface.

In this configuration, it is possible to use the first electrode structure and the second electrode structure as terminals for fixing the photoelectric conversion element. The first electrode structure and the second electrode structure may only protrude from the first side surface, thus enabling a simple structure. Further, they are electrode structures, thus enabling an increase in dimensional accuracy. Thereby, the posture accuracy at the time of disposing the photoelectric conversion element is improved.

In one exemplary aspect of the photoelectric conversion element, the first electrode pattern also serves as the first electrode structure, and the second electrode pattern also serves as the second electrode structure. In this configuration, the manufacturing step of the photoelectric conversion element is simplified.

In one exemplary aspect of the photoelectric conversion element, it is preferable that at least one of the first electrode structure and the second electrode structure has a tapered end portion on an opposite side to the first side surface.

In this configuration, even if the mounting accuracy in the electrode structure is low, the electrode structure is reliably mounted with ease.

In one exemplary aspect of the photoelectric conversion element, the first electrode structure and the second electrode structure are disposed at different positions in a direction orthogonal to the main surface of the substrate.

In this configuration, the stability of placement of the photoelectric conversion elements in two orthogonal directions parallel to the first side surface of the substrate is improved.

In one exemplary aspect of the photoelectric conversion element, it is preferable that the first electrode structure and the second electrode structure are shaped so as to enter inside the substrate from the first side surface.

In this configuration, the bonding stability between the first and second electrode structures and the substrate is improved.

In one exemplary aspect of the photoelectric conversion element, it is preferable that a third electrode structure is provided on the first side surface, and the first electrode structure, the second electrode structure, and the third electrode structure are disposed at positions not aligned on a straight line on the first side surface.

In this configuration, the photoelectric conversion element is supported at three points, and the accuracy and stability of posture holding during placement are further improved.

Further, an optical module is disclosed that includes the photoelectric conversion element described above and a support member on which the photoelectric conversion element is mounted. Moreover, the mounting surface in the support member, on which the photoelectric conversion element is mounted, is formed with a first depression into which the first electrode structure is fitted, and a second depression into which the second electrode structure is fitted. A metal film is formed on a fitting surface between the first depression and the second depression.

In this configuration, the accuracy in the side on which the first and second electrode structures are fitted is also improved. Therefore, the accuracy and stability of the posture holding during placement of the photoelectric conversion element are further improved.

Moreover, the optical module that includes the photoelectric conversion element having the third electrode structure described above, and the support member on which the photoelectric conversion element is mounted, preferably has the following configuration in one exemplary aspect. A mounting surface in the support member, on which the photoelectric conversion element is mounted, is formed with a first depression into which the first electrode structure is fitted, a second depression into which the second electrode structure is fitted, and a third depression into which the third electrode structure is fitted. A metal film is formed on the fitting surfaces of the first depression, the second depression, and the third depression. Lengths of the first electrode structure, the second electrode structure, and the third electrode structure which protrude from the first side surface are larger than depthwise lengths of the first depression, the second depression, and the third depression.

In this configuration, positioning by contact of a metal surface with high accuracy is achieved, and the accuracy and stability of the posture holding during placement of the photoelectric conversion element are further improved.

The exemplary optical module may have the following configuration in one aspect. The optical module includes a lens member disposed on the first surface side of the photoelectric conversion element at a distance from the photoelectric conversion element; and an optical fiber disposed on a side opposite to the photoelectric conversion element with the lens member placed therebetween. The lens member includes a lens member electrode structure on a mounting surface to the support member. The support member includes a lens member depression in which the lens member electrode structure is fitted and a metal film is formed on a fitting surface.

In this configuration, the accuracy in placement of the photoelectric conversion element and the lens member is improved, and the accuracy in the positional relationship therebetween is improved.

Further, the exemplary optical module preferably has the following configuration in one exemplary aspect. The optical fiber is fixed by a fiber attachment member mounted on the support member. The fiber attachment member includes a fiber attachment fitting portion to be fitted to at least one of a substrate of the photoelectric conversion element and the lens member.

In this configuration, the accuracy in the positional relationship between the optical fiber and the components other than the optical fiber is improved.

The exemplary optical module may have the following configuration in one exemplary aspect. The fiber attachment member includes a fiber protrusion on a mounting surface to the support member. The support member includes a fiber depression into which the fiber protrusion is fitted.

In this configuration, the placement accuracy in the optical fiber is improved, and the accuracy in the positional relationship with other components of the optical module is further improved.

According to the present disclosure, it is possible to achieve a photoelectric conversion element having high placement accuracy.

### BRIEF DESCRIPTION OF THE DRAWINGS

FIG. 1 is an external perspective view showing a main configuration of an optical module according to a first exemplary embodiment.

FIG. 2 is an external perspective view of a composite member made up of a surface emitting element and a support member according to the first exemplary embodiment.

FIG. 3 is an exploded perspective view of the composite member made up of the surface emitting element and the support member according to the first exemplary embodiment.

FIG. 4(A) is a front view of a disassembled state of a composite member made up of the surface emitting element and the support member according to the first exemplary embodiment. FIG. 4(B) is a side sectional view of the disassembled state of the composite member made up of the surface emitting element and the support member according to the first exemplary embodiment. FIG. 4(C) is a front view of the composite member made up of the surface emitting element and the support member according to the first exemplary embodiment. FIG. 4(D) is a side sectional view of the composite member made up of the surface emitting element and the support member according to the first exemplary embodiment.

FIG. 5(A) is a front view of a surface emitting element according to a second exemplary embodiment.

FIG. 5(B) is a side sectional view of the surface emitting element according to the second exemplary embodiment.

FIG. 6 is an exploded perspective view of a composite member made up of a surface emitting element and a support member according to a third exemplary embodiment.

FIG. 7(A) is a front view of a disassembled state of the composite member made up of the surface emitting element and the support member according to the third exemplary embodiment. FIGS. 7(B) and 7(C) are side sectional views of the disassembled state of the composite member made up of the surface emitting element and the support member according to the third exemplary embodiment.

FIG. 8 is an enlarged sectional view of a side surface showing a fitted state of a composite member made up of a surface emitting element and a support member according to a fourth exemplary embodiment.

FIG. 9 is an exploded perspective view of an optical module according to a fifth exemplary embodiment.

FIG. 10 is an exploded perspective view of an optical module according to a sixth exemplary embodiment.

### DETAILED DESCRIPTION

In each of the following exemplary embodiments, a surface emitting element such as a vertical cavity surface emitting laser (VCSEL) is exemplified as a photoelectric conversion element, but the following configuration is also applicable to a light-receiving element such as a photodiode.

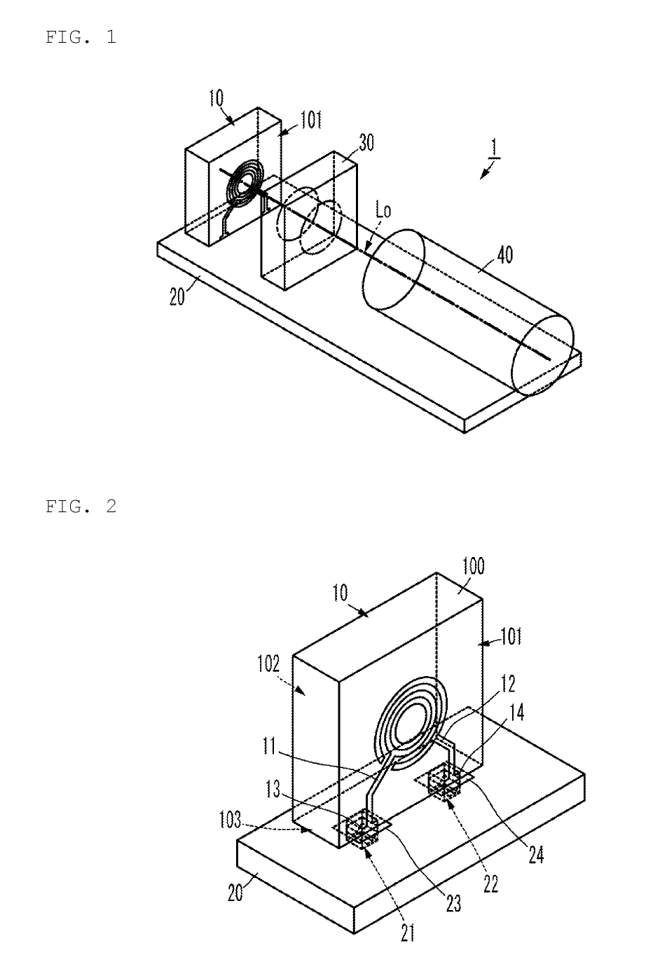

A photoelectric conversion element and an optical module according to a first exemplary embodiment will be described with reference to the drawings. FIG. 1 is an external perspective view showing a main configuration of the optical module according to the first embodiment of the present invention. An optical module 1 includes a surface emitting element 10, a support member 20 (also referred to as a “support”), a lens member 30 (also referred to as a “lens”), and an optical fiber 40. The surface emitting element 10, the lens member 30, and the optical fiber 40 are mounted on the surface of the support member 20. A first surface 101 of the surface emitting element 10 is orthogonal to the surface of the support member 20. The first surface 101 is an emitting surface, and the surface emitting element 10 emits laser light in a direction orthogonal to the emitting surface. The lens member 30 is disposed on the first surface 101 side of the surface emitting element 10 with a distance from the first surface 101. The optical fiber 40 is disposed on the side opposite to the surface emitting element 10 with the lens member 30 placed therebetween. The surface emitting element 10, the lens member 30, and the optical fiber 40 are disposed such that their optical axes Lo coincide with each other. The optical axis Lo is substantially parallel to the surface of the support member 20. In such a configuration, the accuracy in the placement of the surface emitting element 10, the lens member 30, and the optical fiber 40 with respect to the support member 20 is important, and the higher the placement accuracy, the higher the efficiency of the optical module 1.

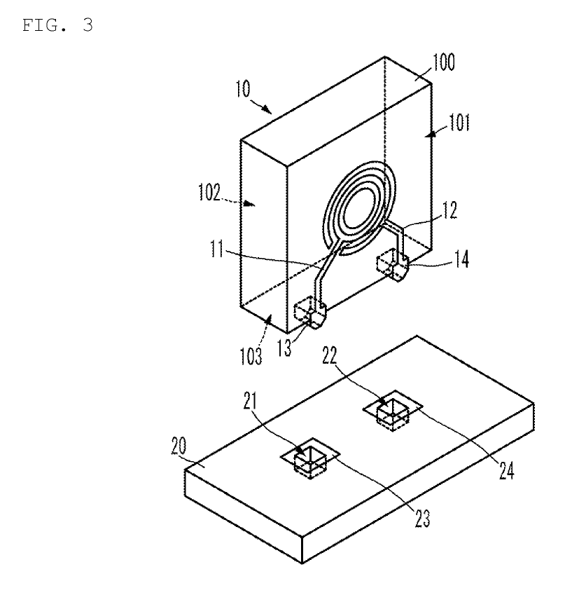

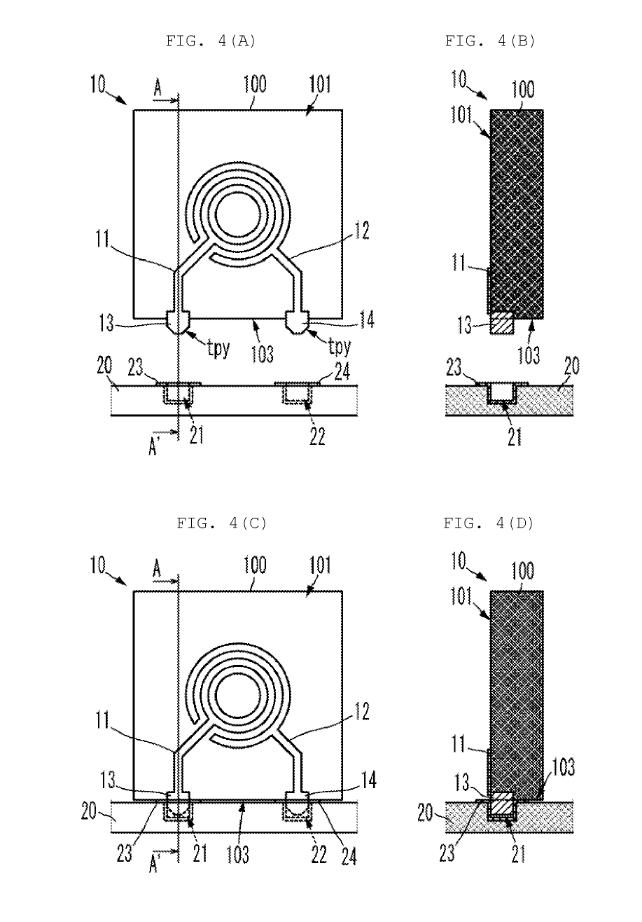

In order to achieve this configuration, the surface emitting element 10 and the support member 20 are configured as follows. Specifically, FIG. 2 is an external perspective view of a composite member made up of the surface emitting element and the support member according to the first embodiment of the present invention. FIG. 3 is an exploded perspective view of the composite member made up of the surface emitting element and the support member according to the first embodiment of the present invention. FIG. 4(A) is a front view of a disassembled state of the composite member made up of the surface emitting element and the support member according to the first embodiment of the present invention. FIG. 4(B) is a side sectional view of the composite member made up of the surface emitting element and the support member according to the first embodiment of the present invention in an exploded state. FIG. 4(B) shows a cross section taken along line A-A′ in FIG. 4(A). FIG. 4(C) is a front view of a composite member made up of the surface emitting element and the support member according to the first embodiment of the present invention. FIG. 4(D) is a side sectional view of the composite member made up of the surface emitting element and the support member according to the first embodiment of the present invention. FIG. 4(D) shows a cross section taken along line A-A′ in FIG. 4(C).

According to the exemplary aspect, the surface emitting element 10 includes a substrate 100 having a rectangular parallelepiped shape. The substrate 100 has a first surface 101 and a second surface 102 which face each other. Preferably, the substrate 100 is formed with a known VCSEL structure made mainly of GaAs and having semi-insulating GaAs, n-type GaAs, or p-type GaAs as a substrate. The surface emitting element 10 generates light resonating in a direction orthogonal to the first surface 101 and the second surface 102 by application of an external voltage, and emits the light from the first surface 101 that can be considered a main surface of the substrate 100. That is, the substrate 100 has an optical element portion. As the surface emitting element, there may be used another semiconductor material such as an InGaAs-based element on an InP substrate, a sapphire, or a GaN-based element on Si.

A first electrode pattern 11 and a second electrode pattern 12 which are a set of electrodes for voltage application are formed on the first surface 101 of the substrate 100 and connected to the n-layer and the p-layer of the VCSEL, respectively. The shapes of the first electrode pattern 11 and the second electrode pattern 12 shown in FIG. 4 are merely examples, and other shapes may be used. According to the exemplary aspect, the first electrode pattern 11 and the second electrode pattern 12 are thin film electrode patterns.

A first electrode structure 13 and a second electrode structure 14 are formed on a first side surface 103 which is orthogonal to the first surface 101 and the second surface 102 of the substrate 100. The first electrode structure 13 is connected to the first electrode pattern 11. The second electrode structure 14 is connected to the second electrode pattern 12. It is noted that the first electrode pattern 11 and the second electrode pattern 12 may be configured so as to also serve as the first electrode structure 13 and the second electrode structure 14, respectively.

The first electrode structure 13 and the second electrode structure 14 are disposed along a side where the first surface 101 and the first side surface 103 intersect. Moreover, each of the first electrode structure 13 and the second electrode structure 14 has a portion protruding outward (i.e., a protrusion or protruding member) from the first side surface 103 and a portion that enters or is embedded inside the substrate 100 from the first side surface 103. Although there may be no portion in each of the first electrode structure 13 and the second electrode structure 14 to enter inside the substrate 100, the presence of this portion allows improvement in bonding reliability between the first electrode structure 13, the second electrode structure 14, and the substrate 100. It is noted that the conduction between the two electrode structures is limited to the active region of the VCSEL, and an insulating layer has been inserted among the substrate 100 and the electrode pattern and the electrode structure so that leakage from other portions does not occur. However, when an insulating substrate is used for the substrate of the substrate 100, the insulating layer is not essential.

The first electrode structure 13 and the second electrode structure 14 have a three-dimensional shape with a small difference in the lengths in three orthogonal directions. In a front view (as viewed in a direction orthogonal to the first surface 101), the end portion of each of the first electrode structure 13 and the second electrode structure 14 on the opposite side to the side entering the substrate 100 has a tapered portion tpy narrowing toward the center.

According to an exemplary aspect, the surface emitting element 10 having such a configuration can be manufactured by the following steps. First, the structure of the VCSEL is formed in the substrate 100. At this time, the substrate 100 is formed to have a size that is capable of forming the first electrode structure 13 and the second electrode structure 14 in a front view.

Next, the side surface of the substrate 100, which is formed in a size capable of forming the first electrode structure 13 and the second electrode structure 14, on the side of the first side surface 103, is etched in accordance with the shapes of the first electrode structure 13 and the second electrode structure 14. Next, an electrode seed layer is formed for a hole formed by this etching. Subsequently, the hole in which the electrode seed layer is formed is filled with an electrode by plating. Thereby, the first electrode structure 13 and the second electrode structure 14 are formed. Specifically, after plating is formed with a sufficient thickness so as to protrude from the first surface 101, the height of the plating surface is matched with the height of the first surface 101 through a polishing step.

Then, the first electrode structure 13 is connected to the first electrode pattern 11, and the second electrode structure 14 is connected to the second electrode pattern 12.

Next, from the first surface 101 or the second surface 102 of the substrate 100 formed with a size capable of forming the first electrode structure 13 and the second electrode structure 14, the substrate 100 is selectively scraped by a photolithography technique or deep RIE such as Bosch process. As a result, the first side surface 103 where the first electrode structure 13 and the second electrode structure 14 protrude is formed.

By using such a configuration, it is possible to form the first electrode structure 13 and the second electrode structure 14 with high dimensional accuracy. In addition, the flatness and the verticality of the first side surface 103 can be increased. Thereby, the installation accuracy in the surface emitting element 10 can be improved.

The support member 20 is an insulating flat plate made of silicon (Si), glass, resin, or the like. The support member 20 may be made of other material so long as it has insulating properties or can form an insulating layer and has high punching accuracy in a direction orthogonal to the flat plate surface.

According to the exemplary aspect, a first depression 21 and a second depression 22 are formed on a mounting surface which is one flat plate surface of the support member 20 as shown. A first metal film 23 is formed in a predetermined range of the surface of the first depression 21 and the mounting surface including the first depression 21. A second metal film 24 is formed in a predetermined range of the surface of the second depression 22 and the mounting surface including the second depression 22.

The first depression 21 and the second depression 22 are formed by dry etching. Since the material for the support member 20 is a material having high punching accuracy, the dimensional accuracy in the first depression 21 and the second depression 22 is high.

According to the exemplary aspect, the first metal film 23 and the second metal film 24 are formed by plating or vapor deposition, the film thickness of which is easy to control. This makes the film thicknesses of the first metal film 23 and the second metal film 24 highly accurate. Further, when the support member 20 is not an insulator, an insulating layer is formed under each metal film in order to ensure insulation between the metal film 23 and the metal film 24. Hence it is possible to achieve the first depression 21 covered with the first metal film 23 and the second depression 22 covered with the second metal film 24 with high dimensional accuracy. In addition, the mounting surface covered with the first metal film 23 and the second metal film 24 can also be achieved with high flatness.

The first electrode structure 13 of the surface emitting element 10 is inserted into the first depression 21 of the support member 20 so as to be fitted with each other. The second electrode structure 14 of the surface emitting element 10 is inserted into the second depression 22 of the support member 20 and is fitted thereto. In other words, each of the first and second depressions 21 and 22 can be structurally configured to receive the first and second electrode structures 13 and 14, respectively.

At this time, the first side surface 103 of the surface emitting element 10 is in contact with the mounting surface of the support member 20 (more specifically, the surfaces of the first metal film 23 and the second metal film 24). Here, the flatness of each surface in contact is high, and the above-mentioned fitted portion has high dimensional accuracy. Therefore, it is advantageously possible to arrange and fix the surface emitting element 10 to the support member 20 with high accuracy.

Furthermore, as shown in the conventional art, a structure is employed in which the first electrode structure 13 and the second electrode structure 14 merely protrude without making the shape of the surface emitting element 10 have a complex uneven shape, and it is thus possible to achieve high placement accuracy with a simple structure. Especially by the use of the manufacturing method described above, it is possible to improve the accuracy in each dimension, and to easily achieve higher placement accuracy.

Further, in the configuration of the present exemplary embodiment, the tips of the first electrode structure 13 and the second electrode structure 14 are tapered. Thus, even if the accuracy is low in the step of inserting the first electrode structure 13 into the first depression 21 and inserting the second electrode structure 14 into the second depression 22, it is possible to reliably insert the first electrode structure 13 into the first depression 21 and insert the second electrode structure 14 into the second depression 22. Thus, the composite member of the surface emitting element 10 and the support member 20 can be more easily manufactured.

Further, in the configuration of the present embodiment, since a pair of electrode structures for applying a voltage for driving the VCSEL is also used for fixing, it is possible to achieve a simpler structure than a configuration in which a fixing protrusion is separately formed. Further, by using a pair of electrode structures used also for fixing, a driving voltage can be directly applied from the driving circuit (not shown), formed on the support member 20, to the surface emitting element 10, and the driving system structure can also be simplified.

It is noted that the lens member 30 can be disposed with high accuracy with respect to the support member 20 by having the same mounting structure as that of the surface emitting element 10 described above. The optical fiber 40 can also be disposed with high accuracy with respect to the support member 20, for example, by using a fixing structure or the like shown in an embodiment described later. Thereby, the surface emitting element 10, the lens member 30, and the optical fiber 40 can be disposed with high accuracy positional relationship, and the highly efficient optical module 1 can be achieved with a simple configuration.

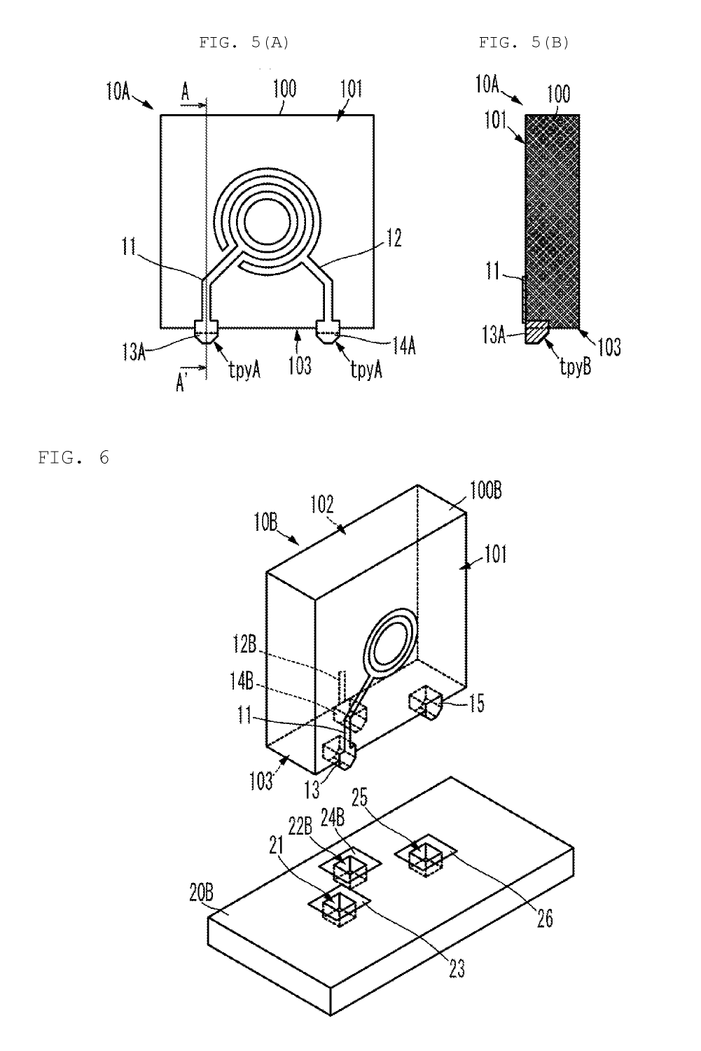

Next, a photoelectric conversion element according to a second exemplary embodiment will be described with reference to the drawings. FIG. 5(A) is a front view of the surface emitting element according to the second embodiment of the present invention. FIG. 5(B) is a side sectional view of the surface emitting element according to the second embodiment of the present invention. FIG. 5(B) shows a cross section taken along line A-A′ in FIG. 5(A).

A surface emitting element 10A according to the present embodiment differs from the surface emitting element 10 according to the first exemplary embodiment in the configurations of a first electrode structure 13A and a second electrode structure 14A. The other configuration is the same as that of the surface emitting element 10 according to the first embodiment.

The first electrode structure 13A and the second electrode structure 14A include a tapered portion tpyA with a tapered width in a front view and a tapered portion tpyB with a tapered width in a side view.

With such a configuration, even when the accuracy in the step of inserting the first electrode structure 13A into the first depression 21 and inserting the second electrode structure 14A into the second depression 22 is low in the two-dimensional region, it is possible to more reliably insert the first electrode structure 13A into the first depression 21 and insert the second electrode structure 14A into the second depression 22. Hence it is possible to more easily manufacture a composite member of the surface emitting element 10A and the support member 20.

It is noted that the tapered portion tpyA and the tapered portion tpyB may not be provided at the same time, and for example only the tapered portion tpyB may be provided.

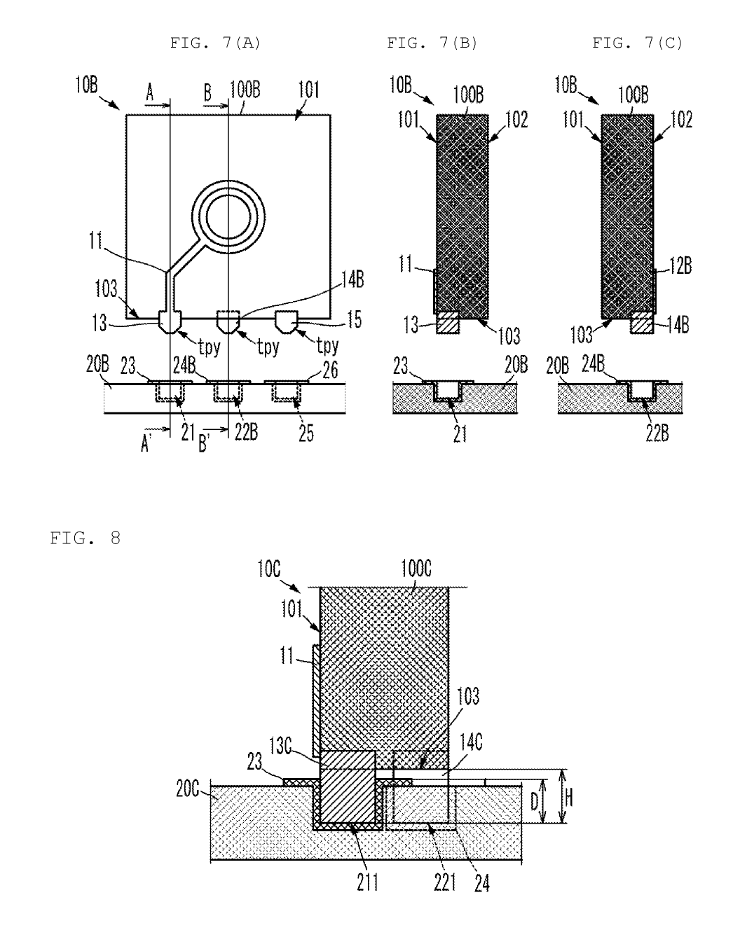

Next, an optical module according to a third exemplary embodiment will be described with reference to the drawings. FIG. 6 is an exploded perspective view of a composite member made up of a surface emitting element and a support member according to the third embodiment of the present invention. FIG. 7(A) is a front view of a disassembled state of the composite member made up of the surface emitting element and the support member according to the third embodiment. FIG. 7(B) and FIG. 7(C) are side sectional views of the disassembled state of the composite member made up of the surface emitting element and the support member according to the third embodiment. FIG. 7(B) shows a cross section taken along line A-A′ in FIG. 7(A). FIG. 7(C) shows a cross section taken along line B-B′ in FIG. 7(A).

A surface emitting element 10B according to the present embodiment differs from the surface emitting element 10 according to the first exemplary embodiment in the addition of a third electrode structure 15 and the placement of a plurality of electrode structures. Further, a support member 20B according to the present embodiment differs from the support member 20 according to the first exemplary embodiment in the addition of a third depression 25 and the placement of a plurality of depressions. The other configuration is the same as the composite member of the surface emitting element and the support member according to the first exemplary embodiment.

In the surface emitting element 10B, the first electrode pattern 11 is formed on the first surface 101 of a substrate 100B, and a second electrode pattern 12B is formed on the second surface 102. In a case where an n-type substrate is used as the substrate of the VCSEL of the substrate 100B, the first electrode structure 13 is connected to the p-layer of the VCSEL and the second electrode structure 14B is connected to the n-type substrate. When a p-type substrate is used as the substrate of the VCSEL of the substrate 100B, the first electrode structure 13 is connected to the n-layer of the VCSEL and the second electrode structure 14B is connected to the p-type substrate of the VCSEL. When an insulating substrate is used as the substrate of the VCSEL of the substrate 100B, the first electrode structure 13 is connected to the n-layer or the p-layer of the VCSEL, the second electrode structure 14B is electrically connected through a via connected with the p-layer or the n-layer formed near the first surface 101. The first electrode structure 13, the second electrode structure 14B, and the third electrode structure 15 are formed in shapes protruding from the first side surface 103. The second electrode structure 14B is connected to the second electrode pattern 12B. The third electrode structure 15 is formed by a construction method similar to that of the first electrode structure 13 and the second electrode structure 14B.

The first electrode structure 13 and the third electrode structure 15 are disposed on the first surface 101 side of the first side surface 103. The second electrode structure 14B is disposed on the second surface 102 side of the first side surface 103. Thereby, the first electrode structure 13, the second electrode structure 14B, and the third electrode structure 15 are disposed so as not to be aligned on a straight line.

With such a configuration, it is possible to suppress not only inclination in a state where the surface emitting element 10B is viewed from the front, but also inclination in a state where the surface emitting element 10B is viewed from the side.

Corresponding to the structure of this surface emitting element 10B, the support member 20B includes a second depression 22B and a third depression 25. The support member 20B includes a second metal film 24B and a third metal film 26. The second metal film 24B covers a predetermined range of the surface of the second depression 22B and the mounting surface including the second depression 22B. The third metal film 26 covers a predetermined range of the surface of the third depression 25 and the mounting surface including the third depression 25.

The second electrode structure 14B is fitted in the second depression 22B and the third electrode structure 15 is fitted in the third depression 25.

With such a configuration, the placement accuracy and fixing stability of the surface emitting element 10B with respect to the support member 20B are further improved.

In the present embodiment, the first electrode pattern 11 is formed on the first surface 101 of the substrate 100B and the second electrode pattern 12B is formed on the second surface 102. However, similarly to the first embodiment, two electrode patterns may be formed on the first surface 101. In this case, the first electrode structure 13 and the second electrode structure 14 may only be disposed on the first surface 101 side of the first side surface 103, and the third electrode structure 15 may only be disposed on the second surface 102 side of the first side surface 103. Electrical connection with the VCSEL is performed via the first electrode structure 13 and the second electrode structure 14.

Next, an optical module according to a fourth exemplary embodiment will be described with reference to the drawing. FIG. 8 is an enlarged sectional view of a side surface showing a fitting state of a composite member made up of a surface emitting element and a support member according to the fourth embodiment of the present invention.

A surface emitting element 10C according to the present embodiment differs from the surface emitting element 10B according to the third exemplary embodiment in that a protruding dimension of each of a first electrode structure 13C, a second electrode structure 14C, and a third electrode structure from the first side surface 103 is specifically set.

As shown, a projecting dimension H of each of the first electrode structure 13C, the second electrode structure 14C, and the third electrode structure from the first side surface 103 is longer than a depth dimension D of each of the first depression 21, the second depression 22, the third depression of a support member 20C.

The tip of the first electrode structure 13C is in contact with the bottom surface 211 of the first depression 21 and the tip of the second electrode structure 14C is in contact with the bottom surface 221 of the second depression 22. Further, the tip of the third electrode structure is in contact with the bottom surface of the third depression.

As described above, each surface of each depression has high flatness and high dimensional accuracy. Further, the flatness and dimensional accuracy in the tips of the first electrode structure 13C, the second electrode structure 14C, and the third electrode structure is also high.

Therefore, as shown in the present embodiment, by bringing the tip of each electrode structure into contact with the bottom surface of each depression, the surface emitting element 10C can be disposed with a higher accuracy with respect to the support member 20C in a desired posture.

In the present embodiment, an aspect has been shown where the first electrode structure 13C, the second electrode structure 14C, and the third electrode structure have the same projecting dimension H, and the first depression 21, the second depression 22, and the third depression have the same depth dimension D. However, so long as a difference between the projecting dimension of the first electrode structure 13C and the depth dimension of the first depression, a difference between the projecting dimension of the second electrode structure 14C and the depth dimension of the second depression, and a difference between the protruding dimension of the third electrode structure and the depth dimension of the third depression are the same, the protruding dimension and the depth dimension may be different from each other. However, by making the projecting dimensions of the plurality of electrode structures and the depth dimensions of the plurality of depressions the same, it is possible to manufacture the composite member in an easier step.

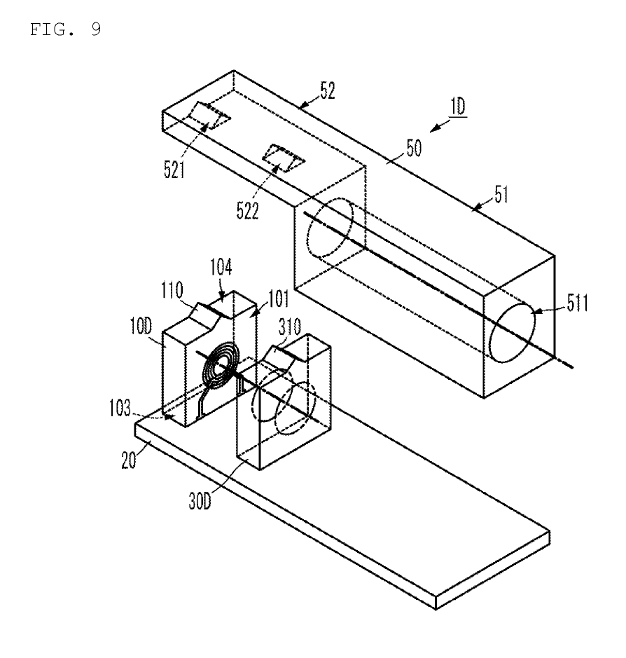

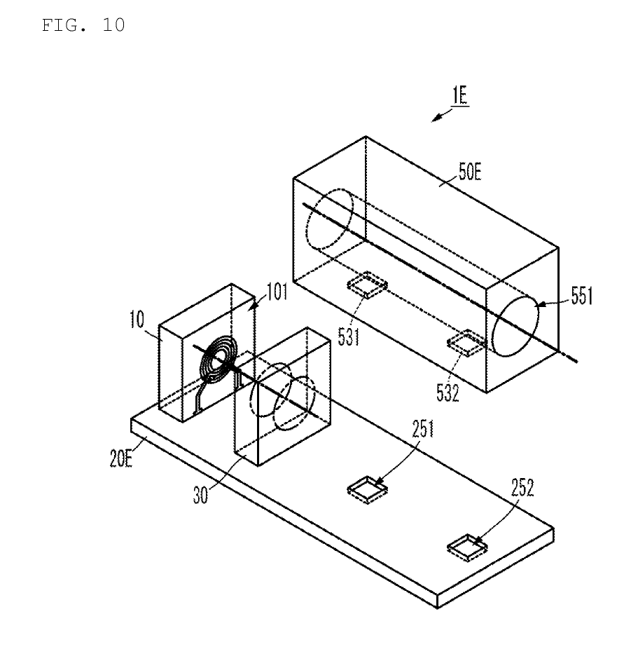

Next, an optical module according to a fifth exemplary embodiment will be described with reference to the drawing. FIG. 9 is an exploded perspective view of the optical module according to the fifth embodiment of the present invention. In FIG. 9, an optical fiber is not shown, but it is attached to a fiber through hole to be described later.

The optical module 1D according to the present embodiment differs from the optical module 1 according to the first exemplary embodiment in that a fiber attachment member 50 is added. Further, in accordance with the addition of the fiber attachment member 50, the shape of a surface emitting element 10D and the shape of a lens member 30D are changed.

The surface emitting element 10D includes a protruding portion 110 on a second side surface 104 facing the first side surface 103. The lens member 30D includes a protrusion 310 on the top surface facing the mounting surface.

The fiber attachment member 50 includes a body portion 51 and a thin portion 52, and the body portion 51 and the thin portion 52 are integrally molded. The fiber attachment member 50 is made of a material having high dimensional accuracy by molding. A fiber through hole 511 is formed in the body portion 51. An optical fiber (not shown) is inserted through the fiber through hole 511 and fixed. In the thin portion 52, depressions 521, 522 to be the fiber attachment fitting portion are formed. The depression 521 is fitted to the protruding portion 110 of the surface emitting element 10D, and the depression 522 is fitted to the protruding portion 310 of the lens member 30D.

With such a structure, the fiber attachment member 50 is disposed and fixed with high positional accuracy with respect to the surface emitting element 10D and the lens member 30D. It is thereby possible to achieve the highly efficient optical module 1D with a simple configuration.

In the present embodiment, the configuration has been shown where the surface emitting element 10D and the lens member 30D are both provided with the protrusions, but one of those may only be provided with the protrusion.

Next, an optical module according to a sixth exemplary embodiment will be described with reference to the drawings. FIG. 10 is an exploded perspective view of the optical module according to the sixth embodiment of the present invention. In FIG. 10, an optical fiber is not shown, but it is mounted in a fiber through hole described later.

The optical module 1E according to the present embodiment differs from the optical module according to the fifth exemplary embodiment in the structure of a fiber attachment member 50E. Further, the optical module 1E according to the present embodiment uses the surface emitting element 10 and the lens member 30 according to the first embodiment.

A fiber through hole 511 is formed in the fiber attachment member 50E. An optical fiber (not shown) is inserted through the fiber through hole 511 and fixed. Fiber protrusions 531, 532 are formed on the bottom surface of the fiber attachment member 50E.

Fiber depressions 251, 252 are formed in the support member 20E. The fiber depression 251 is fitted to the fiber protrusion 531 and the fiber depression 252 is fitted to the fiber protrusion 532. Since the fiber depressions 251, 252 and the fiber protrusions 531, 532 are formed with high dimensional accuracy, the fiber attachment member 50E is disposed with high dimensional accuracy with respect to the support member 20E. By providing the configuration described above, the surface emitting element 10 and the lens member 30 are disposed with high dimensional accuracy. Thus, the fiber attachment member 50E is disposed and fixed with high positional accuracy with respect to the surface emitting element 10 and the lens member 30. It is thereby possible to achieve the highly efficient optical module 1E with a simple configuration.

It is noted that the configuration according to the fifth embodiment and the configuration according to the sixth embodiment may be combined.

### DESCRIPTION OF REFERENCE SYMBOLS

1, 1D, 1E: optical module
10, 10A, 10B, 10C, 10D: surface emitting element
11: first electrode pattern
12, 12B: second electrode pattern
13, 13A, 13C: first electrode structure
14, 14A, 14B, 14C: second electrode structure
15: third electrode structure
20, 20B, 20C, 20E: support member
21: first depression
22, 22B: second depression
23: first metal film
24, 24B: second metal film
25: third depression
26: third metal film
30, 30D: lens member
40: optical fiber
50, 50E: fiber attachment member
51: body
52: thin portion
100, 100B: substrate
101: first surface
102: second surface
103: first side surface
104: second side surface
110: protrusion
211, 221: bottom surface
251, 252: fiber depression
310: protrusion
511: fiber through hole
521, 522: depression
531, 532: fiber protrusion

1. A photoelectric conversion element, comprising:
a substrate having an optical element that is configured to emit light or receive light from a main surface of the substrate;
a first electrode pattern and a second electrode pattern disposed on the substrate and connected to the optical element; and
first and second electrode structures disposed on a first side surface of the substrate that is orthogonal to the main surface and electrically coupled to the first and second electrode patterns, respectively,
wherein the first and second electrode structures include protruding portions that extend from the first side surface of the substrate.

2. The photoelectric conversion element according to claim 1, wherein the first electrode pattern is configured as the first electrode structure and the second electrode pattern is configured as the second electrode structure.

3. The photoelectric conversion element according to claim 1, wherein at least one of the first and second electrode structures comprises a tapered end on a side opposite the first side surface of the substrate.

4. The photoelectric conversion element according to claim 1, wherein the first electrode structure and the second electrode structure are disposed at different positions on the first side surface in a direction orthogonal to the main surface of the substrate.

5. The photoelectric conversion element according to claim 1, wherein the first electrode structure and the second electrode structure each comprise a shape structurally configured to be inserted inside the substrate from the first side surface.

6. The photoelectric conversion element according to claim 1, further comprising a third electrode structure disposed on the first side surface of the substrate.

7. The photoelectric conversion element according to claim 6, wherein the first electrode structure, the second electrode structure, and the third electrode structure are not aligned on a straight line on the first side surface of the substrate.

8. An optical module comprising:
a photoelectric conversion element including:
a substrate having an optical element that is configured to emit light or receive light from a main surface of the substrate,
a first electrode pattern and a second electrode pattern disposed on the substrate and connected to the optical element, and
first and second electrode structures disposed on a first side surface of the substrate that is orthogonal to the main surface and electrically coupled to the first and second electrode patterns, respectively,
wherein the first and second electrode structures include protruding portions that extend from the first side surface of the substrate;
a support member comprising a mounting surface on which the photoelectric conversion element is mounted, the mounting surface including a first depression structurally configured to receive the first electrode structure, and a second depression structurally configured to receive the second electrode structure, and
wherein a metal film is disposed on a fitting surface between the first depression and the second depression.

9. The optical module according to claim 8, further comprising:
a lens disposed on the mounting surface and at a distance from the photoelectric conversion element; and
an optical fiber disposed on the mounting surface with the lens disposed between the optical fiber and the photoelectric conversion element.

10. The optical module according to claim 9,
wherein the lens includes a lens member electrode structure disposed on the mounting surface of the support member, and
wherein the support member includes a lens member depression structurally configured to receive the lens member electrode structure and a metal film disposed on a fitting surface.

11. The optical module according to claim 10, wherein the optical fiber is fixed by a fiber attachment member mounted on the mounting surface of the support member.

12. The optical module according to claim 11, wherein the fiber attachment member includes a fiber attachment fitting member structurally configured to be inserted into at least one of the substrate of the photoelectric conversion element and the lens.

13. The optical module according to claim 10, wherein the fiber attachment member includes a fiber protrusion disposed on the mounting surface of the support member, and the support member includes a fiber depression structurally configured to receive the fiber protrusion.

14. An optical module comprising:
a photoelectric conversion element including:
a substrate having an optical element that is configured to emit light or receive light from a main surface of the substrate,
a first electrode pattern and a second electrode pattern disposed on the substrate and connected to the optical element, and
first and second electrode structures disposed on a first side surface of the substrate that is orthogonal to the main surface and electrically coupled to the first and second electrode patterns, respectively,
a third electrode structure disposed on the first side surface of the substrate,
wherein the first electrode structure, the second electrode structure, and the third electrode structure are not aligned on a straight line on the first side surface of the substrate,
wherein each of the first, second and third electrode structures include protruding portions that extend from the first side surface of the substrate; and
a support member comprising a mounting surface on which the photoelectric conversion element is mounted,
wherein the mounting surface includes a first depression structurally configured to receive the first electrode structure, a second depression structurally configured to receive the second electrode structure, and a third depression structurally configured to receive the third electrode structure, and
wherein a metal film is disposed on fitting surfaces of the first depression, the second depression, and the third depression.

15. The optical module according to claim 14, wherein at respective lengths of the protruding portions of each of the first, second, and third electrode structures are greater than a depthwise length of the first, second, and third depressions in the supporting member, respectively.

16. The optical module according to claim 14, further comprising:
a lens disposed on the mounting surface and at a distance from the photoelectric conversion element; and
an optical fiber disposed on the mounting surface with the lens disposed between the optical fiber and the photoelectric conversion element.

17. The optical module according to claim 16, wherein the lens includes a lens member electrode structure disposed on the mounting surface of the support member, and
wherein the support member includes a lens member depression structurally configured to receive the lens member electrode structure and a metal film disposed on a fitting surface.

18. The optical module according to claim 17, wherein the optical fiber is fixed by a fiber attachment member mounted on the mounting surface of the support member.

19. The optical module according to claim 18, wherein the fiber attachment member includes a fiber attachment fitting member structurally configured to be inserted into at least one of the substrate of the photoelectric conversion element and the lens.

20. The optical module according to claim 18, wherein the fiber attachment member includes a fiber protrusion disposed on the mounting surface of the support member, and the support member includes a fiber depression structurally configured to receive the fiber protrusion.
